(19) United States
(12) Patent Application Publication
(10) Pub. No.: US 2019/0259457 A1
(43) Pub. Date: Aug. 22, 2019

(54) STORAGE DEVICE AND METHOD OF OPERATING THE SAME

(71) Applicant: SK hynix Inc., Gyeonggi-do (KR)

(72) Inventor: Jang Hwan JUN, Gyeonggi-do (KR)

(21) Appl. No.: 16/123,748

(22) Filed: Sep. 6, 2018

(30) Foreign Application Priority Data
Feb. 21, 2018 (KR) 10-2018-0020757

(51) Int. Cl. G11C 16/22; G11C 16/04; G11C 16/26; G11C 16/10

(52) U.S. Cl. CPC G11C 16/225; G11C 16/10; G11C 16/26; G11C 16/0483

(57) ABSTRACT

Provided herein may be a storage device and a method of operating the same. The storage device may program dummy data on a stripe basis. The storage device may include a plurality of memory devices coupled to a common channel, and a memory controller configured to, when a sudden power off is detected, selectively program dummy data to a stripe that is selected from among a plurality of stripes in the plurality of memory devices, depending on whether at least one page in the selected stripe is in an erased state.

### CROSS-REFERENCE TO RELATED APPLICATION

The present application claims priority to Korean patent application number 10-2018-0020757, filed on Feb. 21, 2018, which is incorporated herein by reference in its entirety.

### BACKGROUND

### 1. Field of Invention

Various embodiments of the present disclosure generally relate to a storage device. Particularly, the embodiments relate to a storage device and a method of operating the storage device.

### 2. Description of Related Art

A storage device stores data under the control of a host device such as a computer, a smartphone, or a tablet. Examples of the storage device include a hard disk drive (HDD) which stores data in a magnetic disk, and a solid state drive (SSD) or a memory card which stores data in a semiconductor memory, particularly, a nonvolatile memory.

The storage device may include a memory device in which data is stored and a memory controller which controls the storage of data in the memory device. A memory device may be a volatile memory or a nonvolatile memory. Representative examples of a nonvolatile memory include a read only memory (ROM), a programmable ROM (PROM), an electrically programmable ROM (EPROM), an electrically erasable programmable ROM (EEPROM), a flash memory, a phase-change random access memory (PRAM), a magnetic RAM (MRAM), a resistive RAM (RRAM), and a ferroelectric RAM (FRAM).

### SUMMARY

Various embodiments of the present disclosure are directed to a storage device and a method of operating the storage device, which program dummy data on a stripe basis.

An embodiment of the present disclosure may provide for a method of operating a memory controller, the memory controller controlling a plurality of memory blocks in a plurality of memory devices coupled to a common channel in as a single super block. The method may include reading data from a target stripe that is any one of a plurality of stripes in the single super block, and selectively programming dummy data to the target stripe depending on whether at least one of a plurality of pages in the target stripe is in an erased state, wherein the plurality of stripes are sequentially programmed depending on a sequence of corresponding word lines.

An embodiment of the present disclosure may provide for a method of operating a memory controller, the memory controller controlling a plurality of memory blocks respectively included in a plurality of memory devices coupled to a common channel as a single super block. The method may include sequentially reading data from a plurality of stripes in the single super block in a sequence in which the stripes are programmed, and selectively programming dummy data to a stripe selected from among the plurality of stripes depending on whether at least one page in the selected stripe is in an erased state.

An embodiment of the present disclosure may provide for a storage device. The storage device may include a plurality of memory devices coupled to a common channel, and a memory controller configured to, when a sudden power off is sensed, selectively program dummy data to a stripe that is selected from among a plurality of stripes in the plurality of memory devices, depending on whether at least one page in the selected stripe is in an erased state.

An embodiment of the present disclosure may provide for a memory system. The memory system may include a memory device including a super block having a plurality of stripes each comprising a plurality of pages spanning a plurality of ways; and a controller configured to: control the memory device to perform a program operation on the stripes in a program direction according to a data interleaving scheme; and control, when a sudden power off occurs, the memory device to perform a dummy program operation from a first erased stripe to a reference stripe, wherein the first erased stripe is first in the program direction, among the plurality of stripes, having one or more erased pages, and wherein the reference stripe is first in the program direction, among the plurality of stripes, having erased pages only.

### BRIEF DESCRIPTION OF THE DRAWINGS

FIG. 1 is a block diagram illustrating a storage device according to an embodiment of the present disclosure.

FIG. 2 is a block diagram illustrating exemplary coupling relationships between the memory controller of FIG. 1 and a plurality of memory devices.

FIGS. 3A and 3B are timing diagrams for explaining a program operation and a read operation based on data interleaving according to an embodiment of the present disclosure.

FIG. 4 is a diagram for explaining the concept of a super block, a super page, or a stripe.

FIGS. 5A and 5B are diagrams illustrating data stored in memory devices when a sudden power off occurs and after dummy data is programmed according to an embodiment of the present disclosure.

FIGS. 6A and 6B are diagrams illustrating a method of programming dummy data according to an embodiment of the present disclosure.

FIGS. 7A and 7B are diagrams illustrating a state in which programming of dummy data is completed according to an embodiment of the present disclosure.

FIG. 8 is a diagram illustrating elements of a memory controller included in a storage device according to an embodiment of the present disclosure.

FIG. 9 is a flowchart describing a method of operating a storage device according to an embodiment of the present disclosure.

FIG. 10 is a diagram illustrating an exemplary structure of a memory device of FIG. 1.

FIG. 11 is a diagram illustrating an embodiment of a memory cell array of FIG. 10.

FIG. 12 is a circuit diagram illustrating an example of any one memory block BLKa of the memory blocks BLK1 to BLKz of FIG. 11.

FIG. 13 is a circuit diagram illustrating an example of any one memory block BLKb of the memory blocks BLK1 to BLKz of FIG. 11.

FIG. 14 is a circuit diagram illustrating an example of any one memory block BLKc of a plurality of memory blocks BLK1 to BLKz included in the memory cell array of FIG. 10.

FIG. 15 is a diagram illustrating an embodiment of the memory controller of FIG. 1.

FIG. 16 is a block diagram illustrating a memory card system to which the storage device according to an embodiment of the present disclosure may be applied.

FIG. 17 is a block diagram illustrating an example of a solid state drive (SSD) system to which the storage device according to an embodiment of the present disclosure may be applied.

FIG. 18 is a block diagram illustrating a user system to which the storage device according to an embodiment of the present disclosure may be applied.

### DETAILED DESCRIPTION

Specific structural or functional descriptions provided in this specification are directed to the disclosed embodiments of the present disclosure. The present invention, however, is not limited to the disclosed embodiments.

Rather, aspects of the present invention may be configured or arranged differently than shown or described herein. Thus, the present invention should be construed as covering modifications, equivalents or alternatives that do not depart from the spirit and technical scope of the present disclosure. Also, throughout the specification, reference to “an embodiment” or the like is not necessarily to only one embodiment, and different references to “an embodiment” or the like are not necessarily to the same embodiment(s).

It will be understood that, although the terms “first” and/or “second” may be used herein to identify various elements, these elements should not be limited by these terms. These terms are only used to distinguish one element, from another element that otherwise have the same or similar names. For instance, a first element discussed below could be termed a second element without departing from the teachings of the present disclosure. Similarly, the second element could also be termed the first element.

It will be understood that when an element is referred to as being “coupled” or “connected” to another element, it can be directly coupled or connected to the other element or one or more intervening elements may be present. In contrast, it should be understood that when an element is referred to as being “directly coupled” or “directly connected” to another element, there are no intervening elements present. Other expressions that explain the relationship between elements, such as “between”, “directly between”, “adjacent to” or “directly adjacent to” should be construed in the same way.

The terminology used herein is for the purpose of describing particular embodiments and is not intended to be limiting. In the present disclosure, singular forms are intended to include plural forms and vice versa, unless the context clearly indicates otherwise. It will be further understood that the terms “comprise”, “include”, “have”, and the like. when used in this specification, specify the presence of stated features, integers, steps, operations, elements, components, and/or combinations of them but do not preclude the presence or addition of one or more other features, integers, steps, operations, elements, components, and/or combinations thereof.

Unless otherwise defined, all terms including technical and scientific terms used herein have the same meaning as commonly understood by one of ordinary skill in the art to which the present disclosure pertains. It will be further understood that terms used herein should be interpreted as having a meaning that is consistent with their meaning in the context of this specification and the relevant art and not be interpreted in an idealized or overly formal sense unless expressly so defined herein.

Detailed description of functions and structures well known to those skilled in the art may be omitted to avoid obscuring the subject matter of the present disclosure. Unnecessary description is omitted to make the subject matter of the present disclosure clear.

Various embodiments of the present disclosure will now be described more fully with reference to the accompanying drawings, in which preferred embodiments of the present disclosure are illustrated, so that those skilled in the art can easily carry out the present invention.

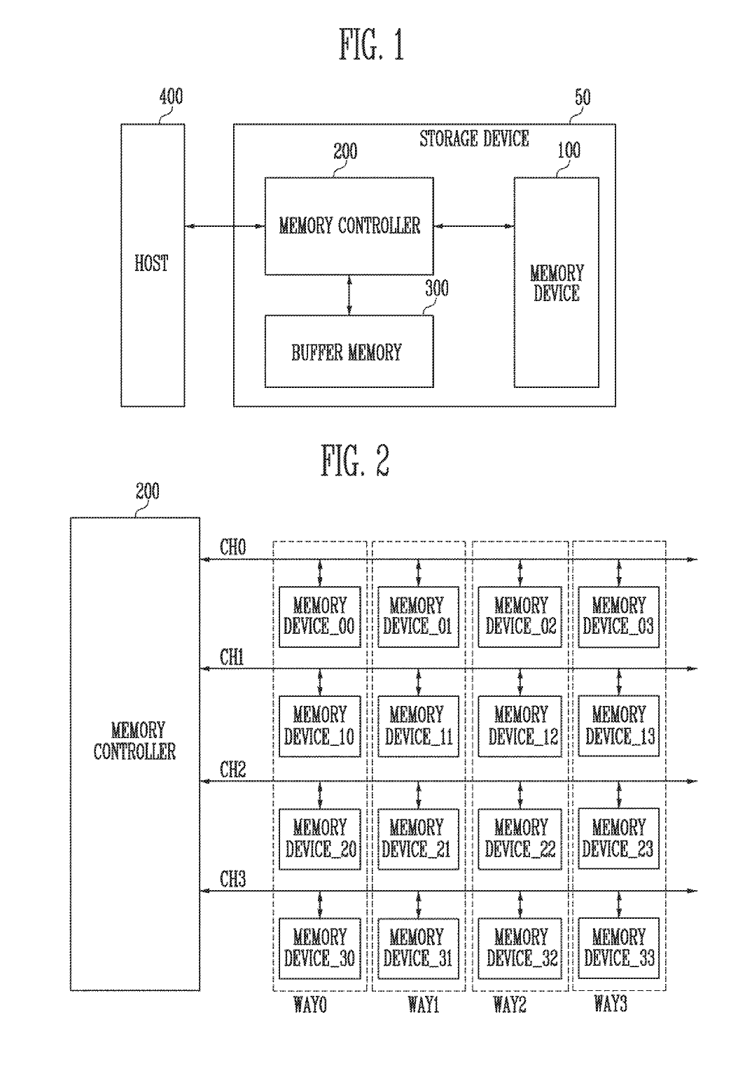

FIG. 1 is a block diagram illustrating a storage device 50 according to an embodiment of the present disclosure.

Referring to FIG. 1, the storage device 50 may include a memory device 100, a memory controller 200, and a buffer memory 300.

The storage device 50 may be a device, such as a mobile phone, a smartphone, an MP3 player, a laptop computer, a desktop computer, a game console, a TV, a tablet PC, or an in-vehicle infotainment system, which stores data under the control of a host 400.

The memory device 100 may store data. The memory device 100 is operated in response to the control of the memory controller 200. The memory device 100 may include a memory cell array including a plurality of memory cells which store data. The memory cell array may include a plurality of memory blocks. Each memory block may include a plurality of memory cells. A single memory block may include a plurality of pages. In an embodiment, each page may be a unit by which data is stored in the memory device 100 or by which data stored in the memory device 100 is read. A memory block may be a unit by which data is erased. In an embodiment, the memory device 100 may take many alternative forms, such as a double data rate synchronous dynamic random access memory (DDR SDRAM), a low power double data rate fourth generation (LPDDR4) SDRAM, a graphics double data rate (GDDR) SDRAM, a Low Power DDR (LPDDR) SDRAM, a Rambus dynamic random access memory (RDRAM), a NAND flash memory, a vertical NAND flash memory, a NOR flash memory device, a resistive RAM (RRAM), a phase-change memory (PRAM), a magnetoresistive RAM (MRAM), a ferroelectric RAM (FRAM), or a spin transfer torque RAM (STT-RAM). In the present specification, by way of example, description is provided on the assumption that the memory device 100 is a NAND flash memory.

In an embodiment, the memory device 100 may be implemented as a three-dimensional (3D) array structure. The present disclosure may be applied not only to a flash memory device in which a charge storage layer is formed of a conductive floating gate (FG), but also to a charge trap flash (CTF) memory device in which a charge storage layer is formed of an insulating layer.

The memory device 100 may receive a command and an address from the memory controller 200, and may access the area of the memory cell array selected by the address. That is, the memory device 100 performs an operation corresponding to the command on the area selected by the address. For example, the memory device 100 may perform a write operation (i.e., program operation), a read operation, and an erase operation. During a program operation, the memory device 100 may program data to the area selected by the address. During a read operation, the memory device 100 may read data from the area selected by the address. During an erase operation, the memory device 100 may erase data stored in the area selected by the address.

The memory controller 200 may control the overall operation of the storage device 50.

When power is applied to the storage device 50, the memory controller 200 may run firmware (FW). When the memory device 100 is a flash memory device, the memory controller 200 may run firmware such as a Flash Translation Layer (FTL) for controlling communication between the host 400 and the memory device 100.

The memory controller 200 may control the memory device 100 so that a program operation, a read operation or an erase operation is performed in response to a request received from the host 400. During the program operation, the memory controller 200 may provide the memory device 100 with a program command, a physical address (PA), and data. During the read operation, the memory controller 200 may provide the memory device 100 with a read command and a physical address (PA). During the erase operation, the memory controller 200 may provide the memory device 100 with an erase command and a physical address (PA).

In an embodiment, the memory controller 200 may autonomously generate a program command, an address, and data without receiving a request from the host 400, and may transmit them to the memory device 100. For example, the memory controller 200 may provide commands, addresses, and data to the memory device 100 so as to perform background operations, such as a program operation for wear leveling and a program operation for garbage collection.

In an embodiment, the memory controller 200 may control data exchange between the host 400 and the buffer memory 300. Alternatively, the memory controller 200 may temporarily store system data for controlling the memory device 100 in the buffer memory 300. For example, the memory controller 200 may temporarily store data, inputted from the host 400, in the buffer memory 300, and may then transmit the data, temporarily stored in the buffer memory 300, to the memory device 100.

In various embodiments, the buffer memory 300 may be used as a working memory or a cache memory of the memory controller 200. The buffer memory 300 may store codes or commands that are executed by the memory controller 200. Alternatively, the buffer memory 300 may store data that is processed by the memory controller 200.

In an embodiment, the memory controller 200 may receive data and logical addresses (LA) from the host 400, and may translate the logical addresses (LA) into physical addresses (PA) indicating the addresses of memory cells which are included in the memory device 100 and in which data is to be stored. Further, the memory controller 200 may store a logical-physical address mapping table, which configures mapping relationships between logical addresses (LA) and physical addresses (PA), in the buffer memory 300.

In an embodiment, the buffer memory 300 may be implemented as a DRAM such as a double data rate SDRAM (DDR SDRAM), a DDR4 SDRAM, a low power double data rate fourth generation (LPDDR4) SDRAM, a graphics double data rate (GDDR) SDRAM, a low power DDR (LPDDR) SDRAM, or a Rambus DRAM (RDRAM), or as a static RAM (SRAM).

In various embodiments, the storage device 50 may not include the buffer memory 300. In this case, one or more volatile memory devices disposed externally to the storage device 50 may function as the buffer memory 300.

In an embodiment, the memory controller 200 may control at least two memory devices 100. Here, the memory controller 200 may control the memory devices 100 in an interleaving manner to improve operating performance.

The host 400 may communicate with the storage device 50 using at least one of various communication methods such as Universal Serial Bus (USB), Serial AT Attachment (SATA), Serial Attached SCSI (SAS), High Speed Interchip (HSIC), Small Computer System Interface (SCSI), Peripheral Component Interconnection (PCI), PCI express (PCIe), Nonvolatile Memory express (NVMe), Universal Flash Storage (UFS), Secure Digital (SD), MultiMedia Card (MMC), embedded MMC (eMMC), Dual In-line Memory Module (DIMM), Registered DIMM (RDIMM), and Load Reduced DIMM (LRDIMM) communication methods.

The storage device 50 may be configured as any one of various types of storage devices depending on a host interface which is a communication method with the host 400. For example, the storage device 50 may be implemented as any one of various types of storage devices, e.g., a solid state disk (SSD), a multimedia card such as an MMC, an embedded MMC (eMMC), a reduced size MMC (RS-MMC), or a micro-MMC, a secure digital card such as an SD, a mini-SD, or a micro-SD, a universal storage bus (USB) storage device, a universal flash storage (UFS) device, a personal computer memory card international association (PCMCIA) card-type storage device, a peripheral component interconnection (PCI)-card type storage device, a PCI express (PCI-E) card-type storage device, a compact flash (CF) card, a smart media card, and a memory stick.

The storage device 50 may be manufactured in any one of various types of package forms. For example, the storage device 50 may be manufactured as package on package (POP), system in package (SIP), system on chip (SOC), multi-chip package (MCP), chip on board (COB), wafer-level fabricated package (WFP), and wafer-level stack package (WSP).

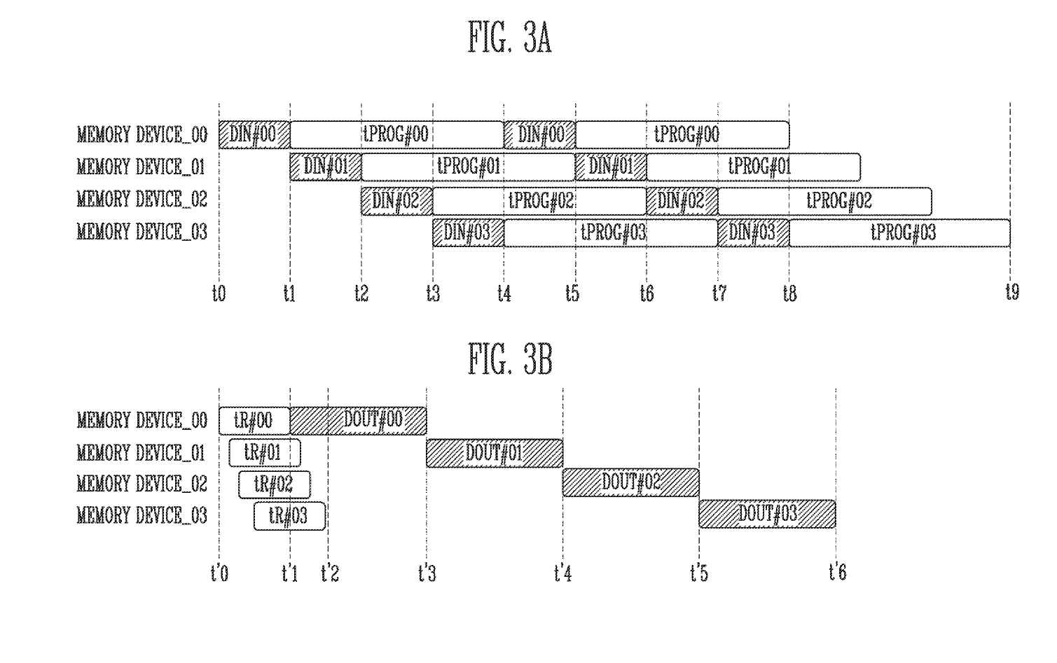

FIG. 2 is a block diagram illustrating exemplary coupling relationships between the memory controller of FIG. 1 and a plurality of memory devices.

Referring to FIG. 2, the memory controller 200 may be coupled to a plurality of memory devices (e.g., memory device_00 to memory device_33) through a plurality of channels CH0 to CH3. The number of channels and/or the number of memory devices coupled to each channel may be different than that shown depending on the system or particular application. For ease of description and clarity, the present disclosure shows and describes the memory controller 200 coupled to the memory devices through four channels, with four memory devices being coupled to each channel.

Memory device_00, memory device_01, memory device_02, and memory device_03 may be coupled in common to channel 0 CH0. The memory device_00, the memory device_01, the memory device_02, and the memory device_03 may communicate with the memory controller 200 through the channel 0 CH0. Since the memory device_00, the memory device_01, the memory device_02, and the memory device_03 are coupled in common to the channel 0 CH0, only one such memory device may communicate with the memory controller 200 at one time. However, these commonly coupled memory devices may simultaneously perform their own internal operations.

Memory device_00, memory device_01, memory device_02, and memory device_03 may be coupled in common to channel 1 CH1. The memory device_00, the memory device_01, the memory device_02, and the memory device_03 may communicate with the memory controller 200 through the channel 1 CH1. Since the memory device_00, the memory device_01, the memory device_02, and the memory device_03 are coupled in common to the channel 1 CH1, only one such memory device may communicate with the memory controller 200 at one time. However, these commonly coupled memory devices may simultaneously perform their own internal operations.

Memory device_20, memory device_21, memory device_22, and memory device_23 may be coupled in common to channel 2 CH2. The memory device_20, the memory device_21, the memory device_22, and the memory device_23 may communicate with the memory controller 200 through the channel 2 CH2. Since the memory device_20, the memory device_21, the memory device_22, and the memory device_23 are coupled in common to the channel 2 CH2, only one such memory device may communicate with the memory controller 200 at one time. However, these commonly coupled memory devices may simultaneously perform their own internal operations.

Memory device_30, memory device_31, memory device_32, and memory device_33 may be coupled in common to channel 3 CH3. The memory device_30, the memory device_31, the memory device_32, and the memory device_33 may communicate with the memory controller 200 through the channel 3 CH3. Since the memory device_30, the memory device_31, the memory device_32, and the memory device_33 are coupled in common to the channel 3 CH3, only one such memory device may communicate with the memory controller 200 at one time. However, these commonly coupled memory devices may simultaneously perform their own internal operations.

The storage device which uses a plurality of memory devices may improve performance through data interleaving, that is data communication based on an interleaving scheme. According to the data interleaving operation, data read and write operations may be performed by units denotes “ways” in a pipelined scheme in a structure in which two or more ways share a single channel with each other. For data interleaving, the memory devices may be managed on a way basis together with channels. In order to maximize parallelism of memory devices coupled to each channel, the memory controller 200 may distribute and allocate consecutive logical memory areas to channels and ways.

For example, the memory controller 200 may transmit commands, control signals including addresses, and data to the memory device_00 through the channel 0 CH0. According to the data interleaving operation, while the memory device_00 is programming the received data to memory cells therein, the memory controller 200 may perform the operation of transmitting commands, control signals including addresses, and data to the memory device_01.

In FIG. 2, the plurality of memory devices may be grouped into four ways WAY0 to WAY3 such that memory devices are coupled to different channels in a single way. Way 0 (WAY0) may include the memory device_00, the memory device_10, the memory device_20, and the memory device_30 respectively coupled to the channels CH0 to CH3. Way 1 (WAY1) may include the memory device_01, the memory device_11, the memory device_21, and the memory device_31 respectively coupled to the channels CH0 to CH3. Way 2 (WAY2) may include the memory device_02, the memory device_12, the memory device_22, and the memory device_32 respectively coupled to the channels CH0 to CH3. Way 3 (WAY3) may include the memory device_03, the memory device_13, the memory device_23, and the memory device_33 respectively coupled to the channels CH0 to CH3.

Each of the channels CH0 to CH3 may be a bus for signals, which is shared and used by memory devices coupled to the corresponding channel.

Although, in FIG. 2, a data interleaving operation in a 4-channel/4-way structure is illustrated, the data interleaving operation may be more efficient as the number of channels increases and the number of ways increases. Thus, the present invention is not limited to a 4-channel/4-way structure.

FIGS. 3A and 3B are timing diagrams for explaining a program operation and a read operation based on data interleaving.

FIG. 3A is a diagram for explaining a program operation, and FIG. 3B is a diagram for explaining a read operation. In FIG. 3, by way of example, the program operation of FIG. 3A and read operation of FIG. 3B are performed on memory device_00 to memory device_03 coupled in common to the channel 0 CH0 of FIG. 2.

Referring to FIG. 3A, during a period from t0 to t1, data input DIN#00 may be performed on the memory device_00. The memory device_00 may receive a program command, an address, and data through channel 0 CH0 while the data input DIN#00 is being performed. Since the memory device_00, the memory device_01, the memory device_02, and the memory device_03 are coupled in common to the channel 0 CH0, remaining memory devices, that is, the memory device_01, the memory device_02, and the memory device_03, cannot use the channel 0 CH0 while the data input DIN#00 is being performed on the memory device_00.

During a period from t1 to t2, data input DIN#01 may be performed on the memory device_01. The memory device_01 may receive a program command, an address, and data through the channel 0 CH0 while the data input DIN#01 is being performed. Since the memory device_00, the memory device_01, the memory device_02, and the memory device_03 are coupled in common to the channel 0 CH0, remaining memory devices, that is, the memory device_00, the memory device_02, and the memory device_03, cannot use the channel 0 CH0 while the data input DIN#01 is being performed on the memory device_01. However, since the memory device_00 receives data during the period from t0 to U. (DIN#00), a program operation may be performed on the memory device_00 from time t1 (tPROG#00).

During a period from t2 to t3, data input DIN#02 may be performed on memory device_02. The memory device_02 may receive a program command, an address, and data through the channel 0 CH0 while the data input DIN#02 is being performed. Since the memory device_00, the memory device_01, the memory device_02, and the memory device_03 are coupled in common to the channel 0 CH0, remaining memory devices, that is, the memory device_00, the memory device_01, and the memory device_03, cannot use the channel 0 CH0 while the data input DIN#02 is being performed on the memory device_02. However, since the memory device_00 receives data during the period from t0 to t1 (DIN#00), a program operation may be performed on the memory device_00 from time t1 (tPROG#00). Further, since the memory device_01 receives data during the period from t1 to t2 (DIN#01), a program operation may be performed on the memory device_01 from time t2 (tPROG#01).

During a period from t3 to t4, data input DIN#03 may be performed on the memory device_03. The memory device_03 may receive a program command, an address, and data through the channel 0 CH0 while the data input DIN#03 is being performed. Since the memory device_00, the memory device_01, the memory device_02, and the memory device_03 are coupled in common to the channel 0 CH0, remaining memory devices, that is, the memory device_00, the memory device_01, and the memory device_02, cannot use the channel 0 CH0 while the data input DIN#03 is being performed on the memory device_03. However, since the memory device_00 receives data during the period from t0 to t1 (DIN#00), a program operation may be performed on the memory device_00 from time t1 (tPROG#00). Further, since the memory device_01 receives data during the period from t1 to t2 (DIN#01), a program operation may be performed on the memory device_01 from time t2 (tPROG#01). Furthermore, since the memory device_02 receives data during the period from t2 to t3 (DIN#02), a program operation may be performed on the memory device_02 from time t3 (tPROG#02).

At time t4, the program operation of the memory device_00 may be completed (tPROG#00).

Thereafter, during a period from t4 to t8, data inputs DIN#00, DIN#01, DIN#02, and DIN#03 may be performed on the memory device_00 to the memory device_03 in the same way as that performed during the period from t0 to t4.

Referring to FIG. 3B, during a period from CO to t′2, the memory device_00 to the memory device_03 may read pieces of data internally corresponding to specific addresses (tR#00 to tR#03). In an embodiment, the memory device_00 to the memory device_03 may read data on a page basis. The memory device_00 may read data during a period from t′0 to t′1 (tR#00), and may output the read data to the memory controller through the channel 0 CH0 during a period from t′1 to t′3 (DOUT#00).

During the period from t′1 to t′3, the memory device_00 outputs the data through the channel 0 CH0 (DOUT#00), and thus the memory device_01, the memory device_02, and the memory device_03 is cannot use the channel 0 CH0.

During a period from t′3 to t′4, the memory device_01 may output the read data to the memory controller through the channel 0 CH0 (DOUT#01). During the period from t′3 to t′4, the memory device_01 outputs the data through the channel 0 CH0 (DOUT#01), and thus the memory device_00, the memory device_02, and the memory device_03 cannot use the channel 0 CH0.

During a period from t′4 to t′5, the memory device_02 may output the read data to the memory controller through the channel 0 CH0 (DOUT#02). During the period from t′4 to t′5, the memory device_02 outputs the data through the channel 0 CH0 (DOUT#02), and thus the memory device_00, the memory device_01, and the memory device_03 cannot use the channel 0 CH0.

During a period from t′5 to t′6, the memory device_03 may output the read data to the memory controller through the channel 0 CH0 (DOUT#03). During period from t′5 to t′6, the memory device_03 outputs the data through the channel 0 CH0 (DOUT#03), and thus the memory device_00, the memory device_01, and the memory device_02 cannot use the channel 0 CH0.

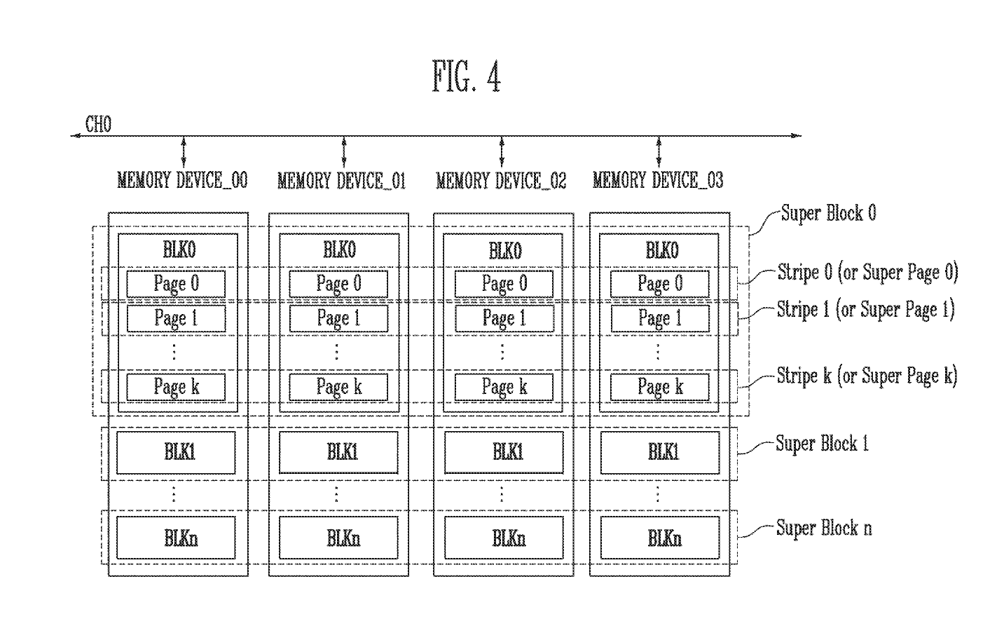

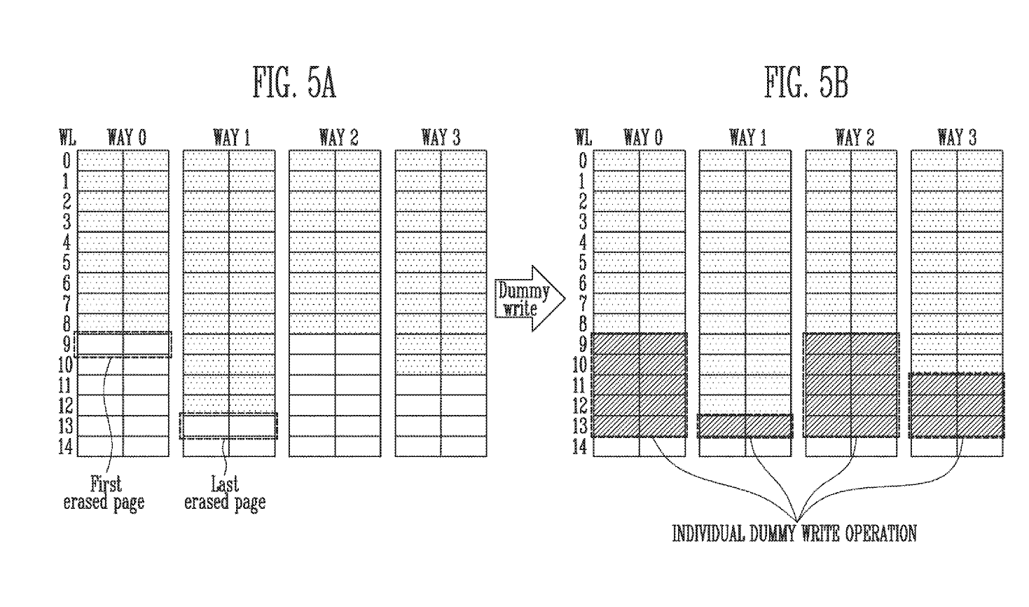

FIG. 4 is a diagram for explaining the concept of a super block, a super page, or a stripe.

Referring to FIG. 4, four memory devices, that is, memory device_00 to memory device_03, may be coupled in common to channel 0 CH0.

In FIG. 4, each of the memory devices (i.e., memory device_00 to memory device_03) may include 0-th to n-th memory blocks BLK0 to BLKn, and each of the memory blocks may include 0-th to k-th pages Page 0 to Page k.

A memory controller, such as memory controller 200, may control memory blocks, in a plurality of memory devices coupled in common to a single channel, on a super block basis. For example, the 0-th memory blocks in the memory device_00 to the memory device_03 may constitute a 0-th super block Super Block 0. Therefore, the memory device_00 to the memory device_03 coupled to channel 0 CH0 may include 0-th to n-th super blocks Super Block 0 to Super Block n.

A single super block may be composed of a plurality of stripes. The term “stripe” may be used interchangeably with the term “super page.”

A single stripe or super page may include a plurality of pages. For example, the 0-th pages Page 0, respectively in the plurality of 0-th memory blocks BLK0 in the 0-th super block Super Block 0, may constitute a 0-th stripe Stripe 0 or a 0-th super page Super Page 0.

Therefore, 0-th to k-th stripes Stripe 0 to Stripe k may be included in a single super block. Alternatively, the 0-th to k-th super pages Super Page 0 to Super Page k may be included in a single super block.

The memory controller 200 may store or read data on a stripe basis or a super page basis when storing data in the memory device_00 to the memory device_03 or reading the stored data.

In this case, a program operation of storing data in a single stripe or super page or a read operation of reading stored data may be performed using data interleaving described with reference to FIG. 3.

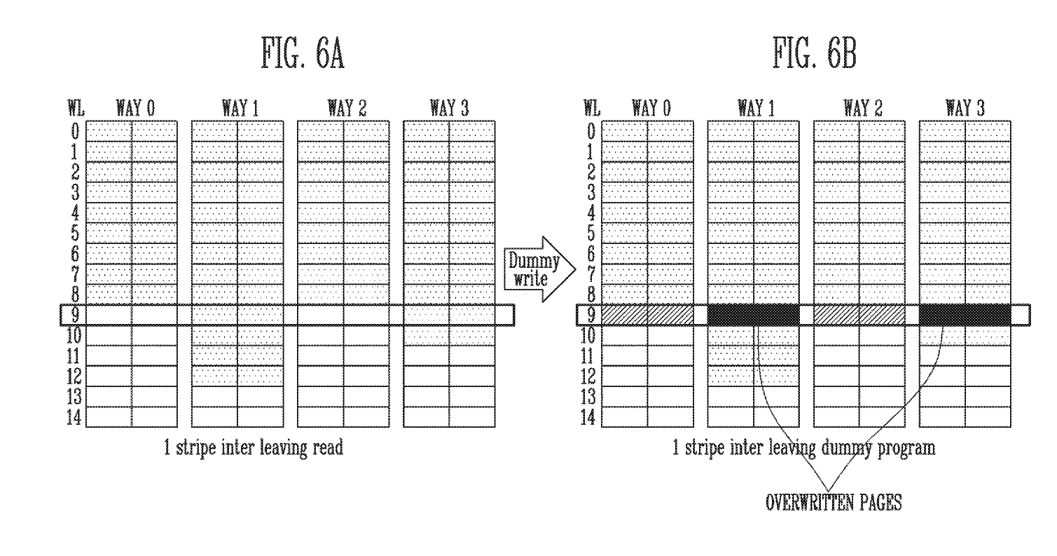

FIGS. 5A and 5B are diagrams illustrating data stored in a memory device when a sudden power off occurs and after dummy data is programmed.

When power supplied to a storage device is suddenly interrupted or lost, a sudden power off (SPO) occurs. When a sudden power off occurs while a program operation is being performed on memory devices in the storage device, the memory controller may control the memory devices so that the program operation, which was interrupted due to the SPO, is resumed after the power is supplied. The memory controller may program dummy data to pages to which the program operation is interrupted due to the sudden power off. Thereafter, the memory controller may resume the interrupted program operation on a page next to the pages to which the dummy data is programmed.

The memory controller may detect pages at which the program operation was interrupted due to the SPO so as to program dummy data into the interrupted pages. Each of memory blocks in each memory device may include a plurality of pages. The plurality of pages may be programmed in a particular program direction, such as in the direction of sequentially increasing page numbers. Memory cells in which data is not stored may have threshold voltages in an erased state. Therefore, the memory controller may read pages in a sequence in which a plurality of pages in the memory block are programmed, and may detect a first erased page, which is a first page having an erased state. In an embodiment, the memory controller may detect a first erased page using, for example, binary scanning.

The memory controller may control the memory devices to program dummy data into the first erased page.

When the memory controller controls memory devices that are coupled to a plurality of channels and are configured using a plurality of ways, it may perform a program operation and a read operation based on data interleaving described above with reference to FIG. 3. Here, the locations of first erased pages may differ from each other for respective ways due to the difference between the speeds of respective memory devices. That is, word lines corresponding to first erased pages may differ from each other for respective memory devices included in the ways.

FIG. 5A illustrates data of memory devices in respective ways when a sudden power off occurs. Since the memory device_00 coupled to way 0 (WAY0) is in a state in which programming up to an eighth word line has been completed, a first erased page is a page corresponding to a ninth word line. Since the memory device_01 coupled to way 1 (WAY1) is in a state in which programming up to a 12-th word line has been completed, a first erased page is a page corresponding to a 13-th word line. Since the memory device_02 coupled to way 2 (WAY2) is in a state in which programming up to an eighth word line has been completed, a first erased page is a page corresponding to a ninth word line. Since the memory device_03 coupled to way 3 (WAY3) is in a state in which programming up to a tenth word line has been completed, a first erased page is a page corresponding to an 11-th word line.

When a program operation or a read operation is performed on a stripe basis or a super page basis, the interrupted program operation may be resumed to the corresponding super block when the power is on after the SPO only when dummy data is programmed up to a reference page. The reference page is a last page in the particular program direction among the first erased pages of the ways. In the example of FIG. 5A, the reference page is the page corresponding to a 13-th word line, which is the last one among the first erased pages of the ways WAY0 to WAY3. In each of the ways, dummy data programming operation may be performed from the first erased page to the reference page.

FIG. 5B is a diagram illustrating a case where programming of dummy data is performed.

In the memory device_00 coupled to the way 0 (WAY0), dummy data is programmed to pages corresponding to word lines ranging from the ninth word line of the first erased page to the 13-th word line of the reference page. In the memory device_01 coupled to the way 1 (WAY1), dummy data is programmed to a page corresponding to the 13-th word line of the first erased page, which is also the reference page. In the memory device_02 coupled to the way 2 (WAY2), dummy data is programmed to pages corresponding to word lines ranging from the ninth word line of the first erased page to the 13-th word line of the reference page. In the memory device_03 coupled to the way 3 (WAY3), dummy data is programmed to pages corresponding to word lines ranging from the 11-th word line of the first erased page to the 13-th word line of the reference page.

In order to program dummy data in the same way as that of the embodiment of FIG. 5, the memory controller should individually detect first erased pages from the memory devices corresponding to respective ways. Further, the memory controller should set a reference page among the first erased pages of the ways, and should individually control respective memory devices so that memory devices corresponding to respective ways program dummy data to pages ranging from the first erased page to the reference page. Therefore, a lot of time may be required for the operation of programming dummy data, and the design of firmware of the memory controller for processing the programming of dummy data may be complicated.

FIGS. 6A and 6B are diagrams illustrating a method of programming dummy data according to an embodiment of the present disclosure.

Referring to FIGS. 6A and 6B, a memory controller, such as memory controller 200, controls memory device_00 to memory device_03 in way 0 to way 3 respectively.

Memory blocks in memory devices in respective ways may be controlled as a unit of a single super block. In FIG. 6, the states of pieces of data stored in memory blocks respectively corresponding to way 0 to way 3 are illustrated in a single super block. For convenience of description, it is assumed that pages corresponding to 15 word lines are included in a single memory block.

FIG. 6A illustrates a state in which data is stored when a sudden power off occurs.

Referring to FIG. 6A, the memory controller 200 may detect pages corresponding to a ninth word line which is a first erased stripe. The first erased stripe may include at least one page in an erased state.

The detection of the first erased stripe by the memory controller 200 may be achieved using various methods. For example, the memory controller 200 may detect the first erased stripe based on pieces of data which are sequentially read on a stripe basis from a 0-th word line in the particular program direction. That is, when at least one piece of data read from a single stripe is detected as in an erased state, the memory controller 200 may set the corresponding stripe as the first erased stripe. In the example of FIG. 6A, the first erase stripe is that corresponding to the ninth word line.

The memory controller 200 may perform a dummy data program operation of programming dummy data to the first erased stripe.

FIG. 6B is a diagram illustrating a case where dummy data is programmed to the first erased stripe corresponding to the ninth word line. Referring to FIG. 6B, pages corresponding to way 0 (WAY0) and way 2 (WAY2) are erased pages, and thus dummy data may be programmed to the pages in the first erased stripe. However, since pieces of data have already been stored in pages corresponding to way 1 (WAY1) and way 3 (WAY3) in the first erased stripe, as illustrated in FIG. 6A, an overwrite program operation may be performed on the pages in which the pieces of data have been stored in the first erased stripe. Therefore, pages corresponding to way 1 and way 3 may be overwritten. Since the previously stored data is not reliable due to the occurrence of a sudden power off, it does not matter if an overwrite program operation is performed on the corresponding page in the first erased stripe.

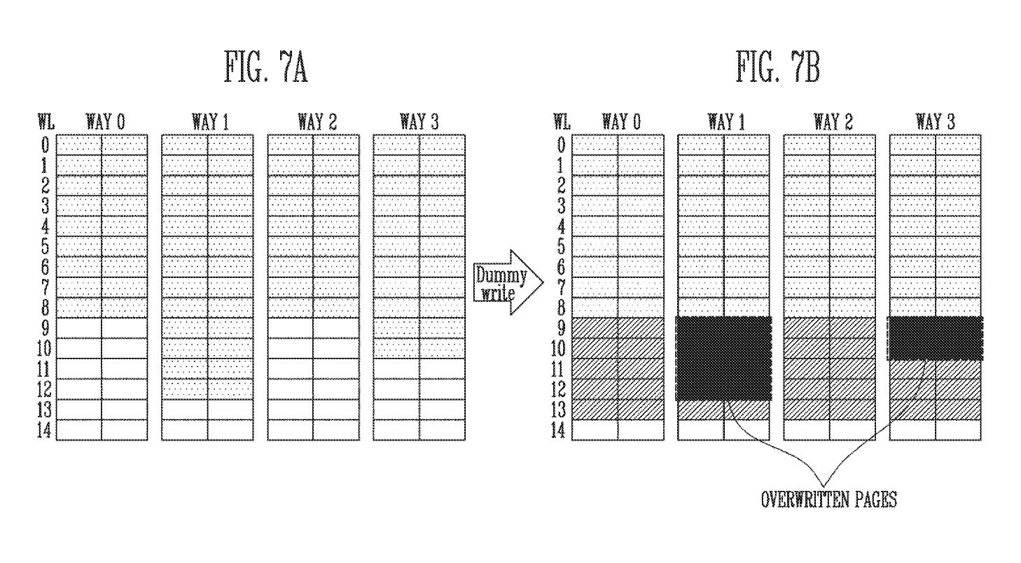

FIGS. 7A and 7B are diagrams illustrating a state in which programming of dummy data is completed according to an embodiment of the present disclosure.

Referring to FIG. 7A, memory device_00 coupled to way 0 (WAY0) is in a state in which programming up to an eighth word line is completely performed when a SPO occurs. Memory device_01 coupled to way 1 (WAY1) is in a state in which programming up to a 12-th word line is completely performed when the SPO occurs. Memory device_02 coupled to way 2 (WAY2) is in a state in which programming up to an eighth word line is completely performed when the SPO occurs. Memory device_03 coupled to way 3 (WAY3) is in a state in which programming up to a tenth word line is completely performed when the SPO occurs.

According to an embodiment of the present disclosure, the memory controller 200 may detect a reference stripe, which may be a first in the particular program direction among the stripes that each include erased pages only. The reference stripe may be detected by reading the stripes of the memory devices in the particular program direction. According to an embodiment of the present disclosure, the memory controller 200 may control the memory devices to perform the dummy data programming operation from the first erased stripe to the reference stripe.

For example, the memory controller 200 may program dummy data to a ninth word line which is a first erased stripe, and may read data from a stripe corresponding to a tenth word line. The stripe corresponding to the tenth word line is not the reference stripe because pages corresponding to way 1 (WAY1) and way 3 (WAY3) are not in an erased state, although pages corresponding to way 0 (WAY0) and way 2 (WAY2) are in the erased state. Therefore, the memory controller 200 may program dummy data to a stripe corresponding to the tenth word line.

Next, the memory controller 200 may read data from a stripe corresponding to an 11-th word line. The stripe corresponding to the 11-th word line is not the reference stripe because a page corresponding to way 1 (WAY1) is not in an erased state, although pages corresponding to way 0 (WAY0), way 2 (WAY2), and way 3 (WAY3) are in the erased state. Therefore, the memory controller 200 may program dummy data to the stripe corresponding to the 11-th word line.

Then, the memory controller 200 may read data from a stripe corresponding to a 12-th word line. The stripe corresponding to the 12-th word line is not the reference stripe because a page corresponding to way 1 (WAY1) is not in an erased state, although pages corresponding to way 0 (WAY©), way 2 (WAY2), and way 3 (WAY3) are in the erased state. Therefore, the memory controller 200 may program dummy data to the stripe corresponding to the 12-th word line.

Next, the memory controller 200 may read data from a stripe corresponding to a 13-th word line. The stripe corresponding to the 13-th word line is the reference stripe because all of pages corresponding to way 0 (WAY0), way 1 (WAY1), way 2 (WAY2), and way 3 (WAY3) are in the erased state. The memory controller 200 may program dummy data to the stripe corresponding to the 13-th word line. After dummy data has been programmed to the reference stripe, the memory controller 200 may resume the interrupted program operation to a stripe corresponding to a 14-th word line.

FIG. 8 is a diagram illustrating elements of a memory controller 200 in a storage device according to an embodiment of the present disclosure.

Referring to FIG. 8, a memory controller 200 may include a sudden power off detector 210, a command generator 220, and a page detector 230.

The sudden power off detector 210 may sense the occurrence of a sudden power off in the storage device 50 described with reference to FIG. 1, and may generate a sensing signal when the supply of power to the storage device 50 is resumed.

The command generator 220 may generate a command and an address so that a read operation for detecting a location, at which a program operation is suspended, from a memory block, in which the program operation is suspended due to a sudden power off, is performed in response to the sensing signal from the sudden power off detector 210. Here, the command generator 220 may generate commands and addresses so that a read operation of reading data on a stripe basis is performed on a plurality of memory devices coupled in common to a single channel, and may provide the generated commands and addresses based on data interleaving operation described above with reference to FIG. 3.

The page detector 230 may detect a first erased stripe based on data acquired by a stripe read operation. For example, the page detector 230 may detect the first erased stripe based on pieces of data which are sequentially read on a stripe basis from a 0-th word line in the particular program direction. That is, when at least one piece of data read from a single stripe is detected as in an erased state, the page detector 230 may set that stripe as the first erased stripe. The first erased stripe may be a stripe in which a program operation is being performed when a sudden power off occurs.

In an embodiment, the page detector 230 may detect a reference stripe. For example, when, as a result of reading data from a single stripe, all pieces of data stored in the plurality of memory devices constituting that stripe are in an erased state, the page detector 230 may set the corresponding stripe as the reference stripe.

The command generator 220 may generate commands and addresses for programming dummy data to memory areas corresponding to the first erased stripe to the reference stripe based on the result of detection by the page detector 230. In an embodiment, the command generator 220 may generate commands and addresses for reading data from a next stripe after programming dummy data to the first erased stripe. Thereafter, the command generator 220 may repeatedly perform the operation of reading data from stripes and the operation of programming dummy data until the reference stripe is detected. In various embodiments, the command generator 220 may sequentially perform first a read operation on a stripe basis until a first erased stripe and a reference stripe are detected. After both the first erased stripe and the reference stripe have been detected, the command generator 220 may generate commands and addresses for programming dummy data to memory areas corresponding to stripes ranging from the first erased stripe to the reference stripe.

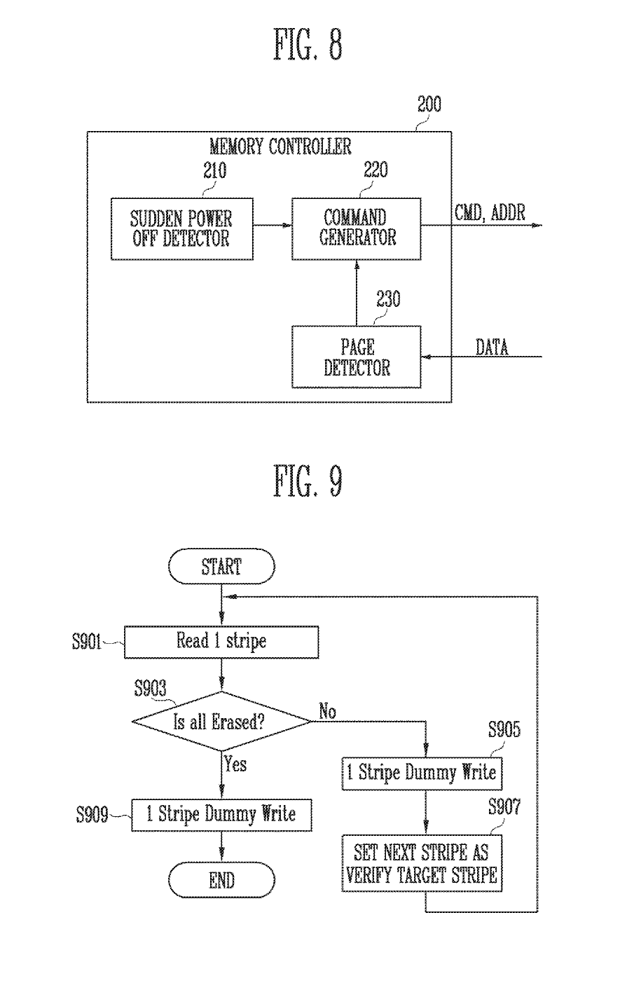

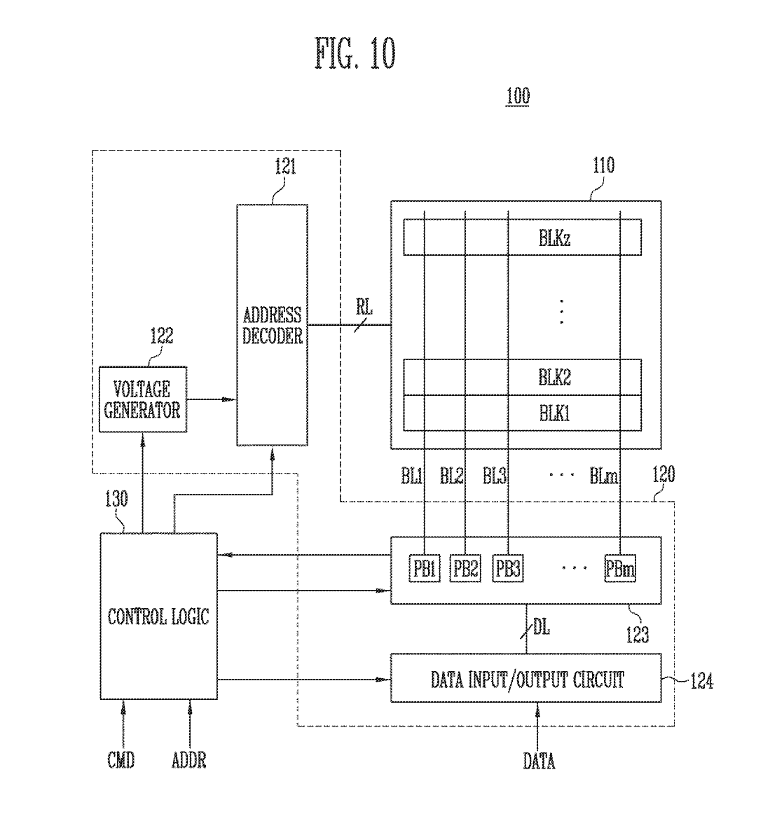

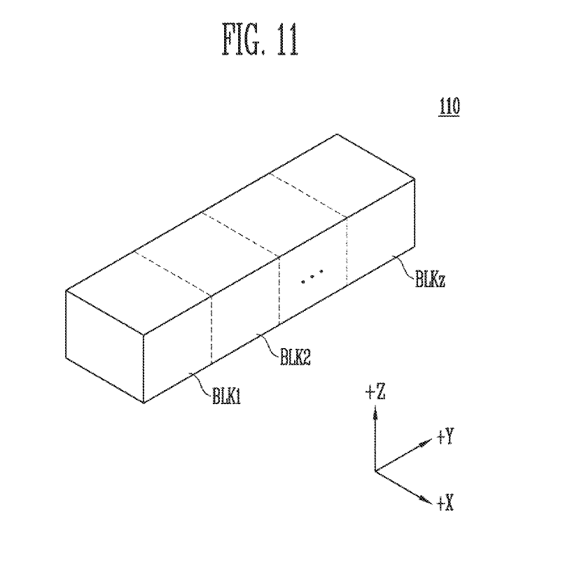

FIG. 9 is a flowchart describing a method of operating a storage device according to an embodiment of the present disclosure.

Referring to FIG. 9, the storage device 50 performs a read operation on a selected stripe at step S901.

At step S903, the storage device 50 may determine whether all of read data from the selected stripe is in an erased state. When it is determined that all of the read data is not in an erased state, the process proceeds to step S905, whereas when it is determined that all of the read data is in the erased state, the process proceeds to step S909.

At step S905, the storage device 50 may program dummy data to the selected stripe from which the data has been read. The dummy data may be programmed to a page in an erased state (i.e., an erased page) in the corresponding stripe. Further, dummy data may be overwritten to pages which are not erased.

At step S907, the storage device 50 may set a next stripe as a verify target stripe to be verified. That is, the storage device 50 selects a next sequential stripe for processing. After step S907, steps S901 to 907 may be repeated.

As a result of the determination at step S903, if all of the read data is in the erased state, the selected stripe may be the reference stripe. At step S909, the storage device 50 may program dummy data to the reference stripe, and may then terminate the process.

FIG. 10 is a diagram illustrating the structure of the memory device 100 of FIG. 1.

Referring to FIG. 10, the memory device 100 may include a memory cell array 110, a peripheral circuit 120, and control logic 130.

The memory cell array 110 includes a plurality of memory blocks BLK1 to BLKz. The plurality of memory blocks BLK1 to BLKz are coupled to an address decoder 121 through row lines RL. The memory blocks BLK1 to BLKz are coupled to a read and write circuit 123 through bit lines BL1 to BLm. Each of the memory blocks BLK1 to BLKz includes a plurality of memory cells. In an embodiment, the plurality of memory cells are nonvolatile memory cells. Memory cells coupled to the same word line are defined as a single page. That is, the memory cell array 110 is composed of a plurality of pages. In an embodiment, each of the plurality of memory blocks BLK1 to BLKz may include one or more dummy cells which may be coupled in series between a drain select transistor and the memory cells and between a source select transistor and the memory cells.

Each of the memory cells of the memory device 100 may be implemented as a single-level cell (SLC) capable of storing a single data bit, a multi-level cell (MLC) capable of storing two data bits, a triple-level cell (TLC) capable of storing three data bits, or a quad-level cell (QLC) capable of storing four data bits.

The peripheral circuit 120 may include an address decoder 121, a voltage generator 122, the read and write circuit 123, and a data input/output circuit 124.

The peripheral circuit 120 may drive the memory cell array 110. For example, the peripheral circuit 120 may drive the memory cell array 110 so that a program operation, a read operation, and an erase operation are performed.

The address decoder 121 is coupled to the memory cell array 110 through row lines RL. The row lines RL may include drain select lines, word lines, source select lines, and a common source line. In an embodiment, the word lines may include normal word lines and dummy word lines. In an embodiment, the row lines RL may further include a pipe select line.

The address decoder 121 is configured to be operated under the control of the control logic 130. The address decoder 121 receives the address ADDR from the control logic 130.

The address decoder 121 is configured to decode a block address of the received address ADDR. The address decoder 121 selects at least one memory block from among the memory blocks BLK1 to BLKz in response to the decoded block address. The address decoder 121 is configured to decode a row address of the received address ADDR. The address decoder 121 may select at least one word line of the selected memory block by applying voltages supplied from the voltage generator 122 to at least one word line WL in response to the decoded row address.

During a program operation, the address decoder 121 may apply a program voltage to the selected word line and apply a pass voltage having a level lower than that of the program voltage to unselected word lines. During a program verify operation, the address decoder 121 may apply a verify voltage to a selected word line and apply a verification pass voltage higher than the verify voltage to unselected word lines.

During a read operation, the address decoder 121 may apply a read voltage to a selected word line and apply a pass voltage higher than the read voltage to unselected word lines.

In an embodiment, the erase operation of the memory device 100 may be performed on a memory block basis. During an erase operation, the address ADDR inputted to the memory device 100 includes a block address. The address decoder 121 may decode the block address and select a single memory block in response to the decoded block address. During the erase operation, the address decoder 121 may apply a ground voltage to word lines coupled to the selected memory block.

In an embodiment, the address decoder 121 may be configured to decode a column address of the received address ADDR. A decoded column address (DCA) may be transferred to the read and write circuit 123. In an exemplary embodiment, the address decoder 121 may include components such as a row decoder, a column decoder, and an address buffer.

The voltage generator 122 is configured to generate a plurality of voltages using an external supply voltage provided to the memory device 100. The voltage generator 122 is operated under the control of the control logic 130.

In an embodiment, the voltage generator 122 may generate an internal supply voltage by regulating the external supply voltage. The internal supply voltage generated by the voltage generator 122 is used as an operating voltage of the memory device 100.

In an embodiment, the voltage generator 122 may generate a plurality of voltages using an external supply voltage or an internal supply voltage. The voltage generator 122 may be configured to generate various voltages required by the memory device 100. For example, the voltage generator 122 may generate a plurality of program voltages, a plurality of pass voltages, a plurality of select read voltages, and a plurality of unselect read voltages.

For example, the voltage generator 122 may include a plurality of pumping capacitors for receiving the internal supply voltage, and may generate a plurality of voltages by selectively activating the pumping capacitors under the control of the control logic 130.

The generated voltages may be supplied to the memory cell array 110 by the address decoder 121.

The read and write circuit 123 includes first to m-th page buffers PB1 to PBm, which are coupled to the memory cell array 110 through the first to m-th bit lines BL1 to BLm, respectively. The first to m-th page buffers PB1 to PBm are operated under the control of the control logic 130.

The first to m-th page buffers PB1 to PBm perform data communication with the data input/output circuit 124. During a program operation, the first to m-th page buffers PB1 to PBm receive data to be stored DATA through the data input/output circuit 124 and data lines DL.

During a program operation, the first to m-th page buffers PB1 to PBm may transfer the data DATA, received through the data input/output circuit 124, to selected memory cells through the bit lines BL1 to BLm when a program pulse is applied to each selected word line. The memory cells in the selected page are programmed based on the transferred data DATA. Memory cells coupled to a bit line to which a program permission voltage (e.g., a ground voltage) is applied may have increased threshold voltages. Threshold voltages of memory cells coupled to a bit line to which a program prohibition voltage (e.g., a supply voltage) is applied may be maintained. During a program verify operation, the first to m-th page buffers may read page data from the selected memory cells through the bit lines BL1 to BLm.

During a read operation, the read and write circuit 123 may read data DATA from the memory cells in the selected page through the bit lines BL, and may output the read data DATA to the data input/output circuit 124.

During an erase operation, the read and write circuit 123 may allow the bit lines BL to float. In an embodiment, the read and write circuit 123 may include a column select circuit.

The data input/output circuit 124 is coupled to the first to m-th page buffers PB1 to PBm through the data lines DL. The data input/output circuit 124 is operated under the control of the control logic 130.

The data input/output circuit 124 may include a plurality of input/output buffers (not illustrated) for receiving input data. During a program operation, the data input/output circuit 124 receives data to be stored DATA from an external controller (not illustrated). During a read operation, the data input/output circuit 124 outputs the data, received from the first to m-th page buffers PB1 to PBm in the read and write circuit 123, to the external controller.

The control logic 130 may be coupled to the address decoder 121, the voltage generator 122, the read and write circuit 123, and the data input/output circuit 124. The control logic 130 may control the overall operation of the memory device 100. The control logic 130 may be operated in response to a command CMD received from an external device.

FIG. 11 is a diagram illustrating an embodiment of the memory cell array of FIG. 10.

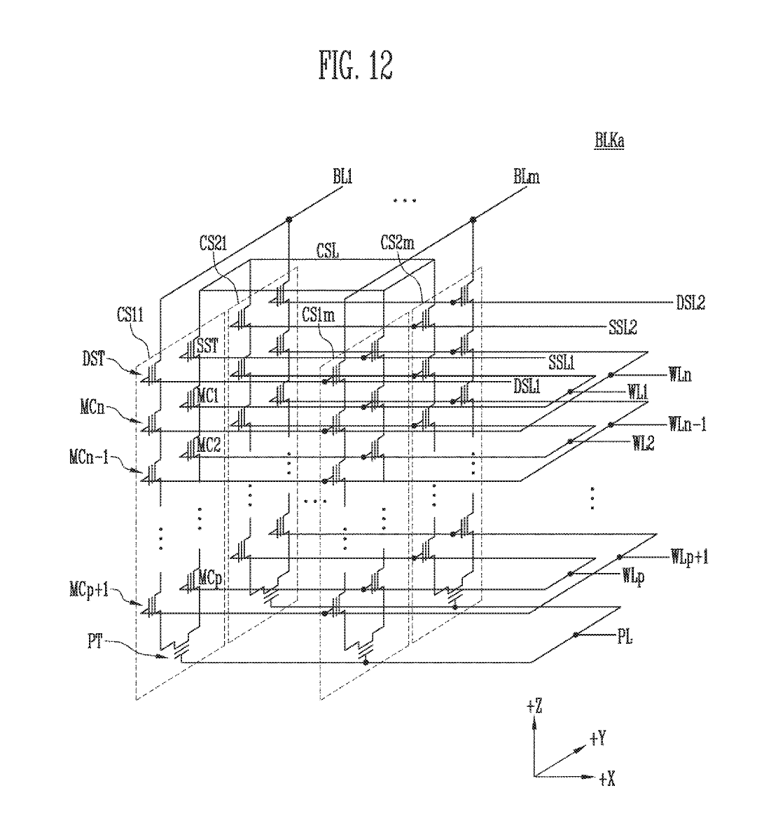

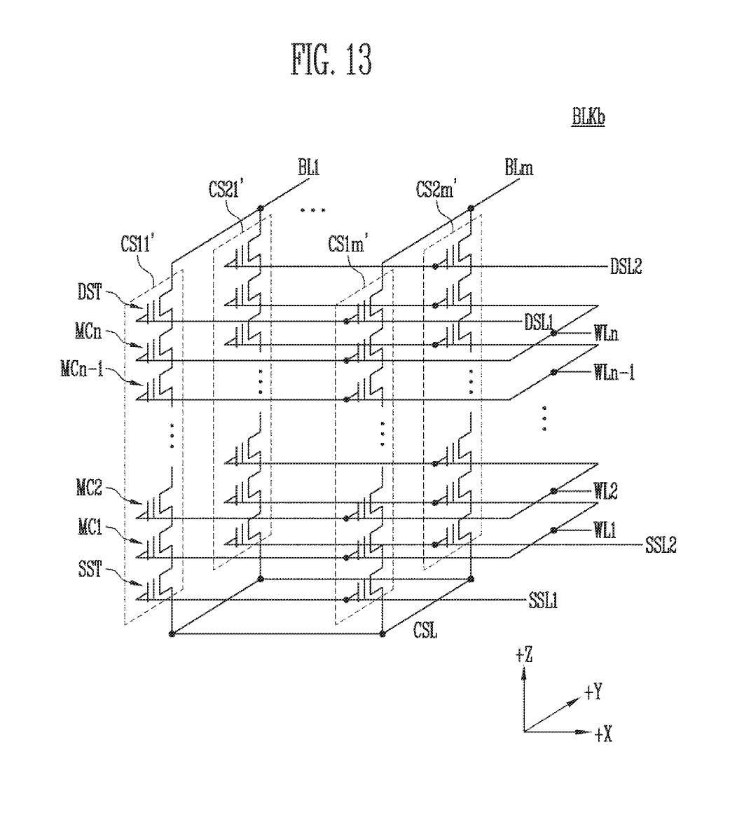

Referring to FIG. 11, the memory cell array 110 includes a plurality of memory blocks BLK1 to BLKz. Each memory block may have a three-dimensional (3D) structure. Each memory block includes a plurality of memory cells stacked on a substrate. Such memory cells are arranged along a positive X (+X) direction, a positive Y (+Y) direction, and a positive Z (+Z) direction. The structure of each memory block will be described in detail below with reference to FIGS. 12 and 13.

FIG. 12 is a circuit diagram illustrating any one memory block BLKa of the memory blocks BLK1 to BLKz of FIG. 10.

Referring to FIG. 12, the memory block BLKa includes a plurality of cell strings CS11 to CS1m and CS21 to CS2m. In an embodiment, each of the cell strings CS11 to CS1m and CS21 to CS2m may be formed in a ‘U’ shape. In the memory block BLKa, m cell strings are arranged in a row direction (i.e., a positive (+) X direction). In FIG. 12, two cell strings are illustrated as being arranged in a column direction (i.e., a positive (+) Y direction). However, this illustration is made for convenience of description, and it will be understood that three or more cell strings may be arranged in the column direction.

Each of the plurality of cell strings CS11 to CS1m and CS21 to CS2m includes at least one source select transistor SST, first to n-th memory cells MC1 to MCn, a pipe transistor PT, and at least one drain select transistor DST.

The select transistors SST and DST and the memory cells MC1 to MCn may have similar structures, respectively. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided to each cell string. In an embodiment, a pillar for providing at least one of the channel layer, the tunneling insulating layer, the charge storage layer, and the blocking insulating layer may be provided to each cell string.

The source select transistor SST of each cell string is connected between the common source line CSL and memory cells MC1 to MCp.

In an embodiment, the source select transistors of cell strings arranged in the same row are coupled to a source select line extending in a row direction, and source select transistors of cell strings arranged in different rows are coupled to different source select lines. In FIG. 12, source select transistors of cell strings CS11 to CS1m in a first row are coupled to a first source select line Sa1. The source select transistors of cell strings CS21 to CS2m in a second row are coupled to a second source select line SSL2.

In an embodiment, source select transistors of the cell strings CS11 to CS1m and CS21 to CS2m may be coupled in common to a single source select line.

The first to nth memory cells MC1 to MCn in each cell string are coupled between the source select transistor SST and the drain select transistor DST.

The first to n-th memory cells MC1 to MCn may be divided into first to p-th memory cells MC1 to MCp and p+1-th to n-th memory cells MCp+1 to MCn. The first to p-th memory cells MC1 to MCp are sequentially arranged in a negative (−) Z direction and are connected in series between the source select transistor SST and the pipe transistor PT. The p+1-th to n-th memory cells MCp+1 to MCn are sequentially arranged in the +Z direction and are connected in series between the pipe transistor PT and the drain select transistor DST. The first to p-th memory cells MC1 to MCp and the p+1-th to n-th memory cells MCp+1 to MCn are coupled to each other through the pipe transistor PT. The gates of the first to nth memory cells MC1 to MCn of each cell string are coupled to first to n-th word lines WL1 to WLn, respectively.

A gate of the pipe transistor PT of each cell string is coupled to a pipeline PL.

The drain select transistor DST of each cell string is connected between the corresponding bit line and the memory cells MCp+1 to MCn. The cell strings in a row direction are coupled to drain select lines extending in a row direction. Drain select transistors of cell strings CS11 to CS1m in the first row are coupled to a first drain select line DSL1. Drain select transistors of cell strings CS21 to CS2m in a second row are coupled to a second drain select line DSL2.

Cell strings arranged in a column direction are coupled to bit lines extending in a column direction. In FIG. 12, cell strings CS11 and CS21 in a first column are coupled to a first bit line BL1. Cell strings CS1m and CS2m in an m-th column are coupled to an m-th bit line BLm.

The memory cells coupled to the same word line in cell strings arranged in a row direction constitute a single page. For example, memory cells coupled to the first word line WL1, among the cell strings CS11 to CS1m in the first row, constitute a single page. Memory cells coupled to the first word line WL1, among the cell strings CS21 to CS2m in the second row, constitute a single additional page. Cell strings arranged in the direction of a single row may be selected by selecting any one of the drain select lines DSL1 and DSL2. A single page may be selected from the selected cell strings by selecting any one of the word lines WL1 to WLn.

In an embodiment, even bit lines and odd bit lines, instead of first to m-th bit lines BL1 to BLm, may be provided. Further, even-numbered cell strings, among the cell strings CS11 to CS1m or CS21 to CS2m arranged in a row direction, may be coupled to the even bit lines, respectively, and odd-numbered cell strings, among the cell strings CS11 to CS1m or CS21 to CS2m arranged in the row direction, may be coupled to the odd bit lines, respectively.

In an embodiment, one or more of the first to n-th memory cells MC1 to MCn may be used as dummy memory cells. For example, one or more dummy memory cells are provided to reduce an electric field between the source select transistor SST and the memory cells MC1 to MCp. Alternatively, the one or more dummy memory cells are provided to reduce an electric field between the drain select transistor DST and the memory cells MCp+1 to MCn. As more dummy memory cells are provided, the reliability of the operation of the memory block BLKa is improved, but the size of the memory block BLKa is increased. As fewer memory cells are provided, the size of the memory block BLKa is reduced, but the reliability of the operation of the memory block BLKa may be deteriorated.

In order to efficiently control the dummy memory cell(s), each of the dummy memory cells may have a required threshold voltage. Before or after the erase operation of the memory block BLKa is performed, a program operation may be performed on all or some of the dummy memory cells. When an erase operation is performed after the program operation has been performed, the threshold voltages of the dummy memory cells control the voltages that are applied to the dummy word lines coupled to respective dummy memory cells, and thus the dummy memory cells may have required threshold voltages.

FIG. 13 is a circuit diagram illustrating an example of any one memory block BLKb of the memory blocks BLK1 to BLKz of FIG. 11.

Referring to FIG. 13, the memory block BLKb includes a plurality of cell strings CS11′ to CS1m′ and CS21′ to CS2m′. Each of the plurality of cell strings CS11′ to CS1m′ and C521′ to CS2m′ extends along a positive Z (+Z) direction. Each of the cell strings CS11′ to CS1m′ and CS21′ to CS2m′ includes at least one source select transistor SST, first to n-th memory cells MC1 to MCn, and at least one drain select transistor DST, which are stacked on a substrate (not illustrated) below the memory block BLKb.

The source select transistor SST of each cell string is connected between a common source line CSL and memory cells MC1 to MCn. The source select transistors of cell strings arranged in the same row are coupled to the same source select line. Source select transistors of cell strings CS11′ to CS1m′ arranged in a first row are coupled to a first source select line SSL1. Source select transistors of cell strings CS21′ to CS2m′ arranged in a second row are coupled to a second source select line SSL2. In an embodiment, source select transistors of the cell strings CS11′ to CS1m′ and CS21′ to CS2m′ may be coupled in common to a single source select line.

The first to nth memory cells MC1 to MCn in each cell string are connected in series between the source select transistor SST and the drain select transistor DST. The gates of the first to n-th memory cells MC1 to MCn are coupled to first to n-th word lines WL1 to WLn, respectively.

The drain select transistor DST of each cell string is connected between the corresponding bit line and the memory cells MC1 to MCn. Drain select transistors of cell strings arranged in a row direction are coupled to drain select lines extending in a row direction. The drain select transistors of the cell strings CS11′ to CS1m′ in the first row are coupled to a first drain select line DSL1. The drain select transistors of the cell strings CS21′ to CS2m′ in the second row are coupled to a second drain select line DSL2.

As a result, the memory block BLKb of FIG. 13 has a circuit similar or equivalent to that of the memory block BLKa of FIG. 12, except that a pipe transistor PT is excluded from each cell string.

In an embodiment, even bit lines and odd bit lines, instead of first to m-th bit lines BL1 to BLm, may be provided. Further, even-numbered cell strings, among the cell strings CS11′ to CS1m′ or CS21′ to CS2m′ arranged in a row direction, may be coupled to the even bit lines, respectively, and odd-numbered cell strings, among the cell strings CS11′ to CS1m′ or CS21′ to CS2m′ arranged in the row direction, may be coupled to the odd bit lines, respectively.

In an embodiment, one or more of the first to n-th memory cells MC1 to MCn may be used as dummy memory cells. For example, the one or more dummy memory cells are provided to reduce an electric field between the source select transistor SST and the memory cells MC1 to MCn. Alternatively, the one or more dummy memory cells are provided to reduce an electric field between the drain select transistor DST and the memory cells MC1 to MCn. As more dummy memory cells are provided, the reliability of the operation of the memory block BLKb is improved, but the size of the memory block BLKb is increased. As fewer memory cells are provided, the size of the memory block BLKb is reduced, but the reliability of the operation of the memory block BLKb may be deteriorated.

In order to efficiently control the dummy memory cell(s), each of the dummy memory cells may have a required threshold voltage. Before or after the erase operation of the memory block BLKb is performed, a program operation may be performed on all or some of the dummy memory cells. When an erase operation is performed after the program operation has been performed, the threshold voltages of the dummy memory cells control the voltages that are applied to the dummy word lines coupled to respective dummy memory cells, and thus the dummy memory cells may have required threshold voltages.

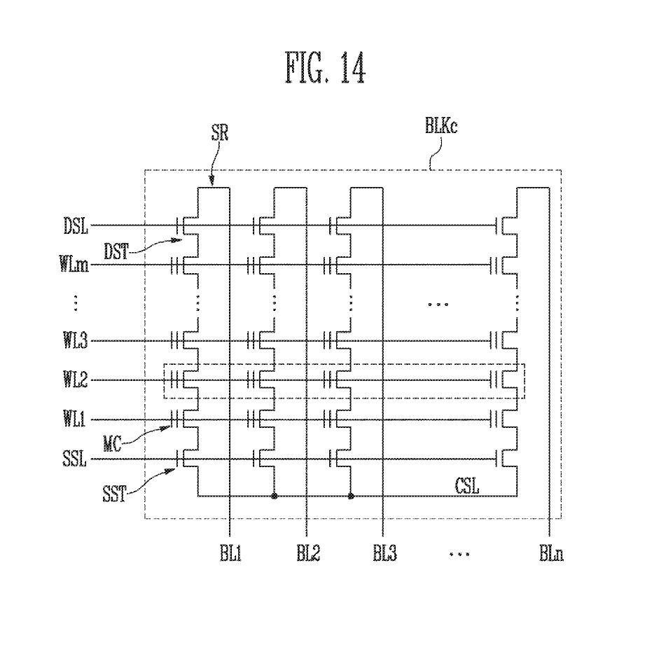

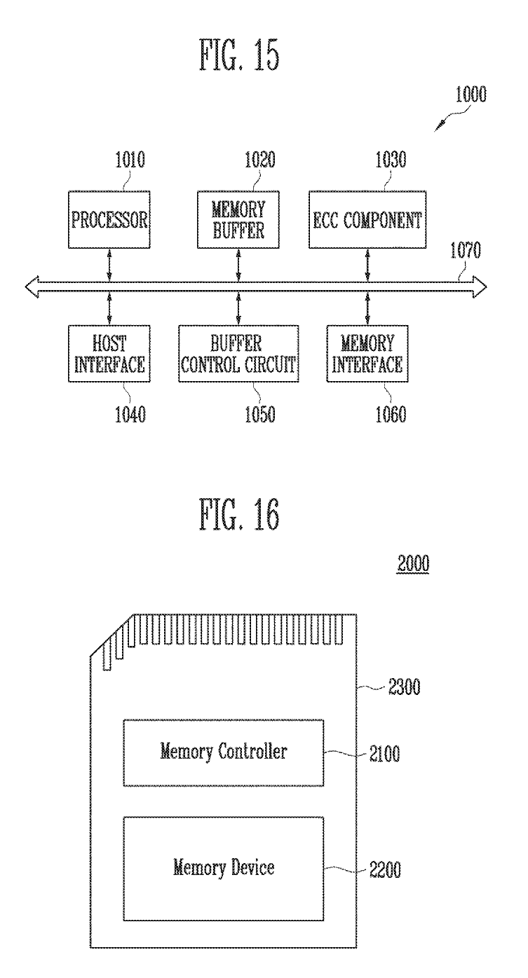

FIG. 14 is a circuit diagram illustrating an example of any one memory block BLKc of a plurality of memory blocks BLK1 to BLKz in the memory cell array 110 of FIG. 10.

Referring to FIG. 14, the memory block BLKc may include a plurality of strings SR. The plurality of strings SR may be respectively coupled to a plurality of bit lines BL1 to BLn. Each string SR may include a source select transistor SST, memory cells MC, and a drain select transistor DST.

The source select transistor SST in each string SR may be coupled between the memory cells MC and a common source line CSL. The source select transistors SST of the plurality of strings SR may be coupled in common to the common source line CSL.

The drain select transistor DST in each string SR may be coupled between the memory cells MC and the corresponding bit line BL. The drain select transistors DST of the plurality of strings SR may be respectively coupled to the plurality of bit lines BL1 to BLn.

In each string SR, a plurality of memory cells MC may be provided between the source select transistor SST and the drain select transistor DST. In each string SR, the memory cells MC may be coupled in series to each other.

In the strings SR, memory cells MC disposed at the same sequential positions from the common source line CSL may be coupled in common to a single word line. The memory cells MC of the plurality of strings SR may be coupled to a plurality of word lines WL1 to WLm.

In the memory block BLKc, an erase operation may be performed on a memory block basis. When the erase operation is performed on a memory block basis, all memory cells MC in the memory block BLKc may be simultaneously erased in response to a single erase request.

FIG. 15 is a diagram illustrating an embodiment of the memory controller 200 of FIG. 1.

A memory controller 1000 is coupled to a host and a memory device. In response to a request received from the host, the memory controller 1000 may access the memory device. For example, the memory controller 1000 may be configured to control write, read, erase, and background operations of the memory device. The memory controller 1000 may provide an interface between the memory device and the host. The memory controller 1000 may run firmware for controlling the memory device.

Referring to FIG. 15, the memory controller 1000 may include a processor 1010, a memory buffer 1020, an error checking and correction (ECC) component 1030, a host interface 1040, a buffer control circuit 1050, a memory interface 1060, and a bus 1070.

The bus 1070 may provide channels between components of the memory controller 1000.

The processor 1010 may control the overall operation of the memory controller 1000 and may perform a logical operation. The processor 1010 may communicate with an external host through the host interface 1040 and also communicate with the memory device through the memory interface 1060. Further, the processor 1010 may communicate with the memory buffer 1020 through the buffer control circuit 1050. The processor 1010 may control the operation of the storage device by using the memory buffer 1020 as a working memory, a cache memory or a buffer memory.

The processor 1010 may perform the function of a flash translation layer (FTL). The processor 1010 may translate a logical block address (LBA), provided by the host, into a physical block address (PBA) through the FTL. The FTL may receive the LBA using a mapping table and translate the LBA into the PBA. Examples of an address mapping method performed through the FTL may include various methods according to a mapping unit. Representative address mapping methods include a page mapping method, a block mapping method, and a hybrid mapping method.

The processor 1010 may randomize data received from the host. For example, the processing unit 1010 may use a randomizing seed to randomize data received from the host. The randomized data may be provided, as data to be stored, to the memory device and may be programmed in the memory cell array.

The processor may derandomize data received from the memory device during a read operation. For example, the processor 1010 may derandomize the data received from the memory device using a derandomizing seed. The derandomized data may be outputted to the host.

In an embodiment, the processor 1010 may run software or firmware to perform randomizing and derandomizing operations.

The memory buffer 1020 may be used as a working memory, a cache memory, or a buffer memory of the processor 1010. The memory buffer 1020 may store codes and commands executed by the processor 1010. The memory buffer 1020 may store data that is processed by the processor 1010. The memory buffer 1020 may include a static RAM (SRAM) or a dynamic RAM (DRAM).

The ECC component 1030 may perform error correction. The ECC component 1030 may perform error correction code (ECC) encoding based on data to be written to the memory device through the memory interface 1060. The ECC-encoded data may be transferred to the memory device through the memory interface 1060. The ECC component 1030 may perform ECC decoding based on data received from the memory device through the memory interface 1060. In an example, the ECC component 1030 may be included as a component of the memory interface 1060.

The host interface 1040 may communicate with the external host under the control of the processor 1010. The host interface 1040 may perform communication using at least one of various communication methods such as Universal Serial Bus (USB), Serial AT Attachment (SATA), Serial Attached SCSI (SAS), High Speed Interchip (HSIC), Small Computer System Interface (SCSI), Peripheral Component Interconnection (PCI), PCI express (PCIe), Nonvolatile Memory express (NVMe), Universal Flash Storage (UFS), Secure Digital (SD), MultiMedia Card (MMC), embedded MMC (eMMC), Dual In-line Memory Module (DIMM), Registered DIMM (RDIMM), and Load Reduced DIMM (LRDIMM) communication methods.

The buffer control circuit 1050 may control the memory buffer 1020 under the control of the processor 1010.

The memory interface 1060 may communicate with the memory device under the control of the processor 1010. The memory interface 1060 may transmit/receive commands, addresses, and data to/from the memory device through channels.

In an embodiment, the memory controller 1000 may not include the memory buffer 1020 and the buffer control circuit 1050, which components may be provided separately or their functions distributed within the memory controller 1000.

In an embodiment, the processor 1010 may control the operation of the memory controller 1000 using codes. The processor 1010 may load codes from a nonvolatile memory device (e.g., ROM) provided in the memory controller 1000. In an embodiment, the processor 1010 may load codes from the memory device through the memory interface 1060.

In an embodiment, the bus 1070 of the memory controller 1000 may be divided into a control bus and a data bus. The data bus may be configured to transmit data in the memory controller 1000, and the control bus may be configured to transmit control information such as commands or addresses in the memory controller 1000. The data bus and the control bus may be isolated from each other, so that neither interferes with nor influences the other. The data bus may be coupled to the host interface 1040, the buffer control circuit 1050, the ECC unit 1030, and the memory interface 1060. The control bus may be coupled to the host interface 1040, the processor 1010, the buffer control circuit 1050, the memory buffer 1020, and the memory interface 1060.

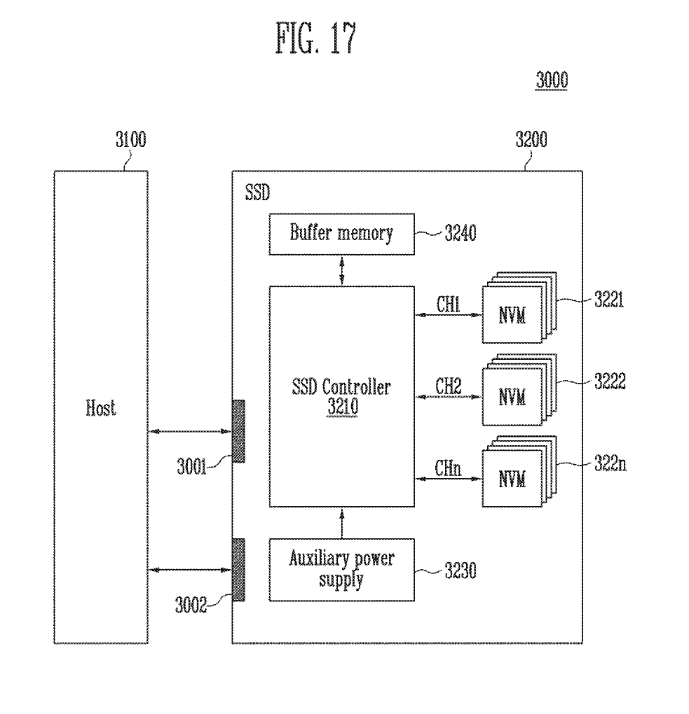

FIG. 16 is a block diagram illustrating a memory card system to which the storage device according to an embodiment of the present disclosure is applied.

Referring to FIG. 16, a memory card system 2000 may include a memory controller 2100, a memory device 2200, and a connector 2300.

The memory controller 2100 is coupled to the memory device 2200. The memory controller 2100 may access the memory device 2200. For example, the memory controller 2100 may control read, write, erase, and background operations of the memory device 2200. The memory controller 2100 may provide an interface between the memory device 2200 and a host. The memory controller 2100 may run firmware for controlling the memory device 2200. The memory controller 2100 may be implemented in the same way as the memory controller 200 described above with reference to FIG. 1.

In an embodiment, the memory controller 2100 may include components, such as a RAM, a processor, a host interface, a memory interface, and an ECC component.

The memory controller 2100 may communicate with an external device through the connector 2300. The memory controller 2100 may communicate with an external device (e.g., a host) based on a specific communication protocol. In an embodiment, the memory controller 2100 may communicate with the external device through at least one of various communication protocols such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer small interface (SCSI), enhanced small disk interface (ESDI), integrated drive electronics (IDE), Firewire, universal flash storage (UFS), Wi-Fi, Bluetooth, and nonvolatile memory express (NVMe) protocols. In an embodiment, the connector 2300 may be defined by at least one of the above-described various communication protocols.

In an embodiment, the memory device 2200 may be implemented as any of various nonvolatile memory devices, such as an Electrically Erasable and Programmable ROM (EEPROM), a NAND flash memory, a NOR flash memory, a Phase-change RAM (PRAM), a Resistive RAM (ReRAM), a Ferroelectric RAM (FRAM), a Spin-Torque Magnetic RAM (STT-MRAM).

The memory controller 2100 and the memory device 2200 may be integrated into a single semiconductor device to configure a memory card such as a PC card (personal computer memory card international association: PCMCIA), a compact flash card (CF), a smart media card (SM or SMC), a memory stick, a multimedia card (MMC, RS-MMC, MMCmicro or eMMC), a SD card (SD, miniSD, microSD, or SDHC), or a universal flash storage (UFS).

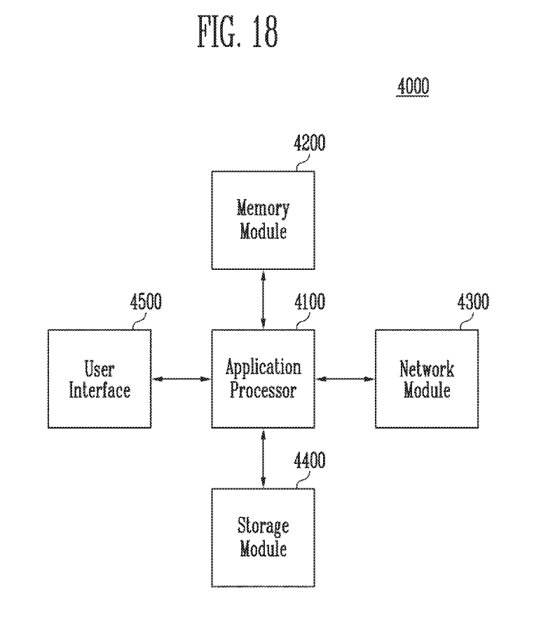

FIG. 17 is a block diagram illustrating an example of a solid state drive (SSD) system to which the storage device according to an embodiment of the present disclosure may be applied.

Referring to FIG. 17, an SSD system 3000 may include a host 3100 and an SSD 3200. The SSD 3200 may exchange signals SIG with the host 3100 through a signal connector 3001 and may receive power PWR through a power connector 3002. The SSD 3200 may include an SSD controller 3210, a plurality of flash memories 3221 to 322n, an auxiliary power supply 3230, and a buffer memory 3240.

In an embodiment, the SSD controller 3210 may perform the function of the memory controller 200 described above with reference to FIG. 1.

The SSD controller 3210 may control the plurality of flash memories 3221 to 322n in response to the signals SIG received from the host 3100. In an embodiment, the signals SIG may be based on the interfaces of the host 3100 and the SSD 3200. For example, the signals SIG may be defined by at least one of various interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer small interface (SCSI), enhanced small disk interface (ESDI), integrated drive electronics (IDE), Firewire, universal flash storage (UFS), Wi-Fi, Bluetooth, and nonvolatile memory express (NVMe) interfaces.

The auxiliary power supply 3230 may be coupled to the host 3100 through the power connector 3002. The auxiliary power supply 3230 may be supplied with power PWR from the host 3100 and may be charged. The auxiliary power supply 3230 may supply the power of the SSD 3200 when the supply of power from the host 3100 is not smoothly performed. In an embodiment, the auxiliary power supply 3230 may be embodied within the SSD 3200. Alternatively, the auxiliary power supply 3230 may be external to the SSD 3200. For example, the auxiliary power supply 3230 may be disposed in a main board and may supply auxiliary power to the SSD 3200.

The buffer memory 3240 functions as a buffer memory of the SSD 3200. For example, the buffer memory 3240 may temporarily store data received from the host 3100 or data received from the plurality of flash memories 3221 to 322n or may temporarily store metadata (e.g., mapping tables) of the flash memories 3221 to 322n. The buffer memory 3240 may include volatile memories such as DRAM, SDRAM, DDR SDRAM, LPDDR SDRAM, and GRAM or nonvolatile memories such as FRAM, ReRAM, STT-MRAM, and PRAM.

FIG. 18 is a block diagram illustrating a user system to which the storage device according to an embodiment of the present disclosure may be applied.

Referring to FIG. 18, a user system 4000 may include an application processor 4100, a memory module 4200, a network module 4300, a storage module 4400, and a user interface 4500.

The application processor 4100 may run components in the user system 4000, an Operating System (OS) or a user program. In an embodiment, the application processor 4100 may include controllers, interfaces, graphic engines, etc. for controlling the components in the user system 4000. The application processor 4100 may be provided as a system-on-chip (SoC).

The memory module 4200 may function as a main memory, a working memory, a buffer memory or a cache memory of the user system 4000. The memory module 4200 may include volatile RAMs such as DRAM, SDRAM, DDR SDRAM, DDR2 SDRAM, DDR3 SDRAM, LPDDR SDRAM, and LPDDR3 SDRAM, or nonvolatile RAMs such as PRAM, ReRAM, MRAM, and FRAM. In an embodiment, the application processor 4100 and the memory module 4200 may be packaged based on package-on-package (POP) and may then be provided as a single semiconductor package.

The network module 4300 may communicate with external devices. For example, the network module 4300 may support wireless communication, such as Code Division Multiple Access (CDMA), Global System for Mobile communication (GSM), wideband CDMA (WCDMA), CDMA-2000, Time Division Multiple Access (TDMA), Long Term Evolution (LTE), WiMAX, WLAN, UWB, Bluetooth, or Wi-Fi communication. In an embodiment, the network module 4300 may be included in the application processor 4100.

The storage module 4400 may store data. For example, the storage module 4400 may store data received from the application processor 4100. Alternatively, the storage module 4400 may transmit the data stored in the storage module 4400 to the application processor 4100. In an embodiment, the storage module 4400 may be implemented as a nonvolatile semiconductor memory device, such as a Phase-change RAM (PRAM), a Magnetic RAM (MRAM), a Resistive RAM (RRAM), a NAND flash memory, a NOR flash memory, or a NAND flash memory having a three-dimensional (3D) structure. In an embodiment, the storage module 4400 may be provided as a removable storage medium (i.e., removable drive), such as a memory card or an external drive of the user system 400.

In an embodiment, the storage module 4400 may include a plurality of nonvolatile memory devices, each of which may be operated in the same way as the memory device described above with reference to FIGS. 10 to 14. The storage module 4400 may be operated in the same way as the storage device 50 described above with reference to FIG. 1.

The user interface 4500 may include interfaces which input data or instructions to the application processor 4100 or output data to an external device. In an embodiment, the user interface 4500 may include one or more user input interfaces such as a keyboard, a keypad, a button, a touch panel, a touch screen, a touch pad, a touch ball, a camera, a microphone, a gyroscope sensor, a vibration sensor, and a piezoelectric device. The user interface 4500 may further include user output interfaces such as a Liquid Crystal Display (LCD), an Organic Light Emitting Diode (OLED) display device, an Active Matrix OLED (AMOLED) display device, an LED, a speaker, and a motor.

In accordance with an embodiment of the present disclosure, when an unmap request is received from the host, the memory controller may store an unmap address, a flag indicating that the corresponding request is the unmap request, and pre-stored unmap pattern data in a write cache buffer. Therefore, when a read request for the unmap address is subsequently received, the memory controller may output the unmap pattern data stored in the write cache buffer in response to the read request in the same way as a typical read request.

In accordance with the present disclosure, there are provided a storage device and a method of operating the storage device, which program dummy data on a stripe basis.

While embodiments of the present disclosure have been disclosed, those skilled in the art will appreciate that various modifications, additions and substitutions are possible, without departing from the scope and spirit of the present disclosure. Therefore, the scope of the present disclosure is defined by the appended claims and equivalents of the claims rather than by the description preceding them.

In the above-discussed embodiments, steps may be selectively performed or skipped. In addition, the steps in each embodiment may be performed in different orders than disclosed herein. More generally, the disclosed embodiments aim to help those skilled in this art more clearly understand the present disclosure rather than limit the bounds of the present disclosure.

Embodiments of the present disclosure have been described with reference to the accompanying drawings. Specific terms or words used in the description should be construed in accordance with the spirit of the present disclosure without limiting the subject matter thereof. It should be understood that many variations and modifications of the basic inventive concept described herein still fall within the spirit and scope of the present disclosure as defined in the appended claims and their equivalents.

What is claimed is:

1. A method of operating a memory controller, the memory controller controlling a plurality of memory blocks in a plurality of memory devices coupled to a common channel as a single super block, the method comprising:
reading data from a target stripe that is any one of a plurality of stripes in the single super block; and
selectively programming dummy data to the target stripe depending on whether at least one of a plurality of pages in the target stripe is in an erased state,
wherein the plurality of stripes are sequentially programmed depending on a sequence of corresponding word lines.

2. The method according to claim 1, wherein selectively programming the dummy data comprises, when all of the plurality of pages in the target stripe are in the erased state, programming dummy data to the target stripe.

3. The method according to claim 1, wherein selectively programming the dummy data comprises:
detecting, among a plurality of pages in the target stripe, a first erased page in the erased state;
programming the dummy data to the first erased page; and
reading data from a next stripe corresponding to a word line to be programmed subsequent to the target stripe.

4. The method according to claim 1, wherein selectively programming the dummy data comprises, when all of the plurality of pages in the target stripe are not in the erased state, reading data from a next stripe corresponding to a word line to be programmed subsequent to the target stripe.

5. The method according to claim 1, wherein selectively programming the dummy data comprises:
detecting, as the target stripe, a first erased stripe in which at least one of the plurality of pages therein is in the erased state;
sequentially reading data from next stripes corresponding to word lines to be programmed subsequent to the target stripe; and
detecting a reference stripe in which all of pages therein are in the erased state, among the next stripes corresponding to the word lines to be programmed subsequent to the target stripe.

6. The method according to claim 5, wherein selectively programming the dummy data further comprises programming the dummy data to stripes from the first erased stripe to the reference stripe.

7. The method according to claim 1, wherein reading the data from the target stripe and programming the dummy data are performed based on data interleaving operation.

8. A method of operating a memory controller, the memory controller controlling a plurality of memory blocks respectively included in a plurality of memory devices coupled to a common channel as a single super block, the method comprising:
sequentially reading data from a plurality of stripes in the single super block in a sequence in which the stripes are programmed; and
selectively programming dummy data to a stripe selected from among the plurality of stripes depending on whether at least one page in the selected stripe is in an erased state.

9. The method according to claim 8, wherein selectively programming the dummy data comprises:
detecting a first erased stripe in which at least one of a plurality of pages therein is in the erased state;
detecting a reference stripe in which all of the plurality of pages therein are in the erased state; and
programming the dummy data to stripes from the first erased stripe to the reference stripe.

10. A storage device, comprising:
a plurality of memory devices coupled to a common channel; and
a memory controller configured to, when a sudden power off is detected, selectively program dummy data to a stripe selected from among a plurality of stripes in the plurality of memory devices, depending on whether at least one page in the selected stripe is in an erased state.

11. The storage device according to claim 10, wherein the memory controller is configured to control a plurality of memory blocks respectively included in the plurality of memory devices as a single super block.

12. The storage device according to claim 11, wherein the single super block comprises a plurality of stripes.

13. The storage device according to claim 12, wherein the memory controller comprises:
a command generator configured to generate a read command and an address for reading data from the selected stripe; and
a page detector configured to detect a first erased stripe in which at least one of a plurality of pages therein is in the erased state.

14. The storage device according to claim 13, wherein the command generator is configured to generate a command and an address for programming dummy data to the first erased stripe.

15. The storage device according to claim 10, wherein the memory controller is configured to control the plurality of memory devices coupled to the common channel based on data interleaving operation.
